(19) United States
(12) Patent Application Publication
(10) Pub. No.: US 2026/0013121 A1
(43) Pub. Date: Jan. 8, 2026

(54) NON-VOLATILE MEMORY DEVICE AND METHOD FOR MANUFACTURING THE SAME

(71) Applicant: IOTMEMORY TECHNOLOGY INC., Taipei City (TW)

(72) Inventors: Der-Tsyr Fan, Taoyuan City (TW); I-Hsin Huang, Taoyuan City (TW); Tzung-Wen Cheng, New Taipei City (TW); Yu-Ming Cheng, Yilan County (TW); Chen-Ming Tsai, Miaoli County (TW); I-Chun Chuang, Hsinchu County (TW)

(21) Appl. No.: 19/216,667

(22) Filed: May 22, 2025

Related U.S. Application Data
(60) Provisional application No. 63/666,683, filed on Jul. 2, 2024.

(51) Int. Cl. H10B 41/30

(52) U.S. Cl. CPC H10B 41/30

(57) ABSTRACT

A method for manufacturing a non-volatile memory device includes: forming two stack structures on a substrate, and a gap is formed between the stack structures; forming a floating gate layer covering the two stack structures and filled into the gap, wherein the floating gate layer includes a recess region; filling a first mask layer into the recess region; removing portions of the first mask layer to form a first mask in the recess region; removing portions of the floating gate layer to leave the floating gate layer in the gap, where top surface of the floating gate layer in the gap is laterally separated from the first mask; converting the top surface of the floating gate layer into second masks under the coverage of the first mask; removing the first mask in the recess region; and etching the floating gate layer using the second masks as an etch mask.

### CROSS REFERENCE TO RELATED APPLICATIONS

This application claims the benefit of U.S. Provisional Application No. 63/666,683, filed on Jul. 2, 2024. The content of the application is incorporated herein by reference.

### BACKGROUND OF THE INVENTION

### 1. Field of the Invention

The invention relates to a semiconductor device, and more particularly, to a non-volatile memory device and a method for manufacturing the same.

### 2. Description of the Prior Art

Since a non-volatile memory can, for instance, repeatedly perform operations such as storing, reading, and erasing data, and since stored data is not lost after the non-volatile memory is shut down, the non-volatile memory has been extensively applied in personal computers and electronic equipment.

A conventional structure of non-volatile memory has a stack-gate structure, including a tunneling oxide layer, a floating gate, a coupling dielectric layer, and a control gate disposed on a substrate in order. When a programming or erase operation is performed on such a flash memory device, a suitable voltage is respectively applied to the source region, the drain region, and the control gate, such that electrons are injected into a floating gate, or electrons are pulled out from the floating gate.

In the programming and erase operation of the non-volatile memory, a greater gate-coupling ratio (GCR) between the floating gate and the control gate generally means a lower operating voltage is needed for the operation, and the operating speed and the efficiency of the flash memory are significantly increased as a result. However, during programming or erase operations, electrons have to be injected into or pulled out of the floating gate through a tunneling oxide layer disposed under the floating gate, which often causes damages to the structure of the tunneling oxide layer and thus reduces the reliability of the memory device.

In order to increase the reliability of the memory device, an erase gate is adopted and incorporated into to the memory device, which is capable of pulling the electrons from the floating gate by applying a positive voltage to the erase gate. Thus, since the electrons in the floating gate is pulled out through a tunneling oxide layer disposed on the floating gate rather than through the tunneling oxide layer disposed under the floating gate, the reliability of the memory device is further improved.

US20240162315 A1 discloses a non-volatile memory device that is relevant to the present application but is not considered prior art. Referring to FIG. 1 and FIG. 2 of US20240162315 A1, where FIG. 1 is a schematic top view of a non-volatile memory device, and FIG. 2 is a schematic cross-sectional view corresponding to line A-A′, line B-B,′ and line C-C′ of FIG. 1. A common practice for defining floating gates shown in US20240162315 A1 would include first planarizing the floating gate layer, which is made of polysilicon, to expose two adjacent select gate stacks, and then utilizing photolithography and etching processes to pattern the planarized floating gate layer between the select gate stacks.

However, the photolithographic patterning inevitably induces variations in the dimensions (e.g., width) of the floating gate and this variation often causes significant changes in the erase voltage applied to the erase gate during an erase operation, thereby deteriorating the uniformity of electrical characteristics among memory devices.

Therefore, there remains a need for an improved manufacturing method for the memory device to minimize the above mentioned width variation in the floating gates.

### SUMMARY OF THE INVENTION

The invention provides a non-volatile memory device and a method for manufacturing the same. The non-volatile memory device is capable of erasing the stored data more efficiently and/or exhibits improved uniformity in electrical characteristics across memory devices.

According to some embodiments of the present disclosure, a method for manufacturing a non-volatile memory device is disclosed and includes the following steps: providing a substrate; forming two stack structures on the substrate, each stack structure comprising a select gate layer and a select gate dielectric layer, and a gap being formed between the stack structures; forming a floating gate layer on the substrate, the floating gate layer covering the two stack structures and the substrate, and filled into the gap, wherein the floating gate layer comprises a recess region; filling a first mask layer into the recess region; removing an upper portion of the first mask layer to form a first mask in the recess region; removing an upper portion of the floating gate layer to leave the floating gate layer in the gap, wherein two top surfaces of the floating gate layer in the gap are laterally separated from the first mask; converting the two top surfaces of the floating gate layer into second masks under the coverage of the first mask; removing the first mask in the recess region; and etching the floating gate layer using the second masks as an etch mask.

According to some embodiments of the present disclosure, a non-volatile memory device is disclosed and includes at least one memory cell. The memory cell includes a substrate, a select gate, and a floating gate. The select gate is disposed on the substrate. The floating gate is disposed on the substrate and laterally separated from the select gate. The floating gate includes two first top edges, two first sidewalls, and two second sidewalls. The first top edges is disposed opposite each other along a first direction, each first top edge being higher than the top surface of the select gate, wherein one of the first top edges is adjacent to the select gate and laterally separated from a bottom surface of the floating gate. The first sidewalls are disposed opposite each other along the first direction and connected respectively to the two first top edges. The second sidewalls are disposed opposite each other along a second direction different from the first direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a non-volatile memory device according to some embodiments of the present disclosure.

FIG. 2 is a schematic cross-sectional view of a non-volatile memory device corresponding to line A-A′, line B-B,′ and line C-C′ of FIG. 1 according to some embodiments of the present disclosure.

FIG. 3 is an enlarged cross-sectional view of a region of a non-volatile memory device shown in FIG. 2 according to some embodiments of the present disclosure.

FIG. 4 to FIG. 13 are cross-sectional views at various stages in the manufacturing of non-volatile memory devices according to some embodiments of the present disclosure.

FIG. 14 to FIG. 15 are cross-sectional views at various stages in the manufacturing of non-volatile memory devices according to alternative embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

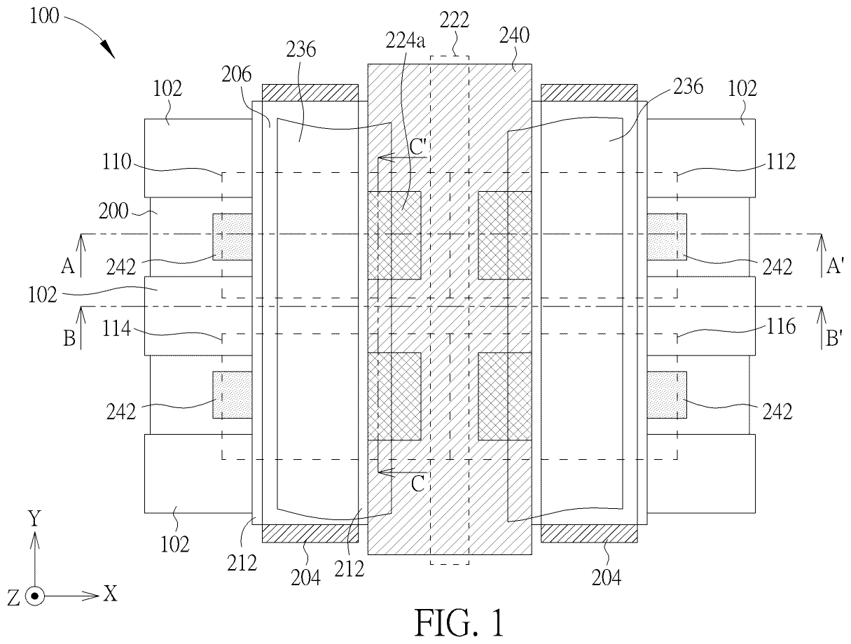

FIG. 1 is a schematic top view of a non-volatile memory device according to some embodiments of the present disclosure. Referring to FIG. 1, a non-volatile memory device 100 can be a NOR flash memory device including at least one memory cell, such as four memory cells accommodated in the first, second, third, and fourth memory cell regions 110, 112, 114, and 116, respectively. The structures in the first memory cell region 110 and the second memory cell region 112 have a mirror image of each other, and the structures in the third memory cell region 114 and the fourth memory cell region 116 have a mirror image of each other. According to one embodiment of the present disclosure, the non-volatile memory device 100 includes more than four memory cells, and these memory cells can be arranged in an array with numerous rows and columns.

Referring to FIG. 1, the non-volatile memory device includes a substrate 200 and an isolation structure 102. The substrate 200 can be a semiconductor substrate, such as a silicon substrate or silicon-on-insulator (SOI) substrate, but not limited thereto. The isolation structure 102 can be made an insulating material and is used to define active areas 103 of the memory cells.

Each of the memory cells includes a source region 222 and a drain region 244 disposed in the active area 103 defined by the isolation structure 102. The source region 222 and the drain region 244 can be doped regions of the same conductivity type, such as n-type or p-type. The conductivity type of the source region 222 and the drain region 244 is different from the conductivity type of the substrate 200, or different from the conductivity type of a doped well (not shown) used to accommodate the source region 222 and the drain region 244. The source region 222 can be disposed at one end of the active area 103, and the drain region 244 can be arranged at another end of the active area 103. According to some embodiments of the present disclosure, the source region 222 is a continuous region extending along a Y-direction and shared by the memory cells in the same column.

Each memory cell can further include a select gate 204 disposed on the substrate 200 and adjacent to the drain region 244. The select gate 204 can extend along the Y-direction and shared by the memory cells that are located in the same column. The select gate 204 can be made of conductive material such as poly silicon or metal, and select gate 204 can act as a word line configured to turn on/off the channel regions of the memory cells that are disposed underneath the word line. Thus, the channel regions of the memory cells in the same column can be turned on or off concurrently.

A dielectric spacer 212 can be disposed on the sidewalls of the select gate 204 in order to insulate the select gate 204 from other conductive components. The dielectric spacer 212 can be a single-layered, double-layered, or a multi-layered spacer disposed on each sidewall of the select gate 204, but not limited thereto.

Each memory cell also includes a floating gate 224a disposed on the substrate 200 and adjacent to the source region 222. Thus, the floating gate 224a is disposed at one side of the select gate 204, and the drain region 242 is disposed at another side of the select gate 204. The floating gates 224a are made of conductive material, such as polysilicon or other semiconductor. The floating gates 224a are spaced apart from each other so that the electric current could not directly transmitted between the floating gates 224. Since the floating gates 224a are spaced apart from each other, each the floating gate 224a can be programed or erased independently to thereby determine the state of each memory cell, such as state “1” or state “0”.

Each memory cell also includes an upper gate structure 236 disposed on the select gate 204. The upper gate structure 236 can extend along the Y-direction and shared by the memory cells that are located in the same column. According to different requirements, the upper gate structure 236 can act as an erase gate structure configured to pull the electrons out of the floating gate 224a through the top corner and/or top edge of the floating gate 224a, or act as not only the erase gate structure but also a control gate structure configured to attract hot carriers from the carrier channel into the floating gate 224a.

A middle structure 240 is disposed in the gap between adjacent floating gates 224a to surround the periphery of the floating gates 224a. According to different requirements, the middle structure 240 can include an insulating structure configured to prevent leakage current between adjacent floating gates 224, or the middle structure 240 can act as a control gate structure configured to make hot carriers (e.g. electrons) injected from the channel into the floating gate 224a.

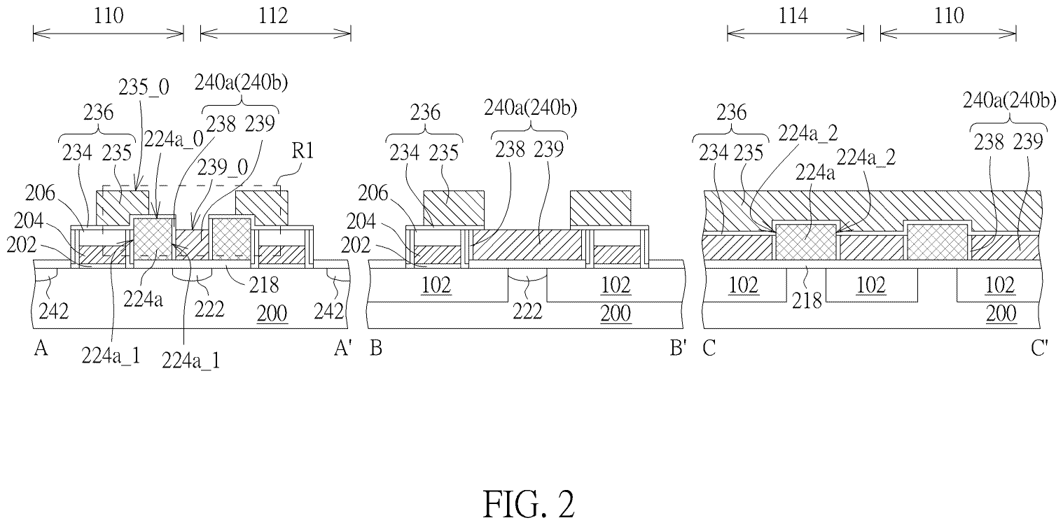

FIG. 2 is a schematic cross-sectional view of a non-volatile memory device corresponding to line A-A′, line B-B′, and line C-C′ of FIG. 1 according to some embodiments of the present disclosure, where an upper gate structure covers a floating gate and a middle structure. Referring to view AA′ of FIG. 2, the drain regions 242 are disposed in the first memory cell region 110 and the second memory region 112, respectively. The source region 222 is disposed at the boundary of the first memory cell region 110 and the second memory region 112.

For the memory cell in the first memory cell region 110, a select gate dielectric layer 302 is disposed between the substrate 200 and the select gate 204. By biasing the select gate 204 at predetermined voltage, the carrier channel under the select gate dielectric layer 302 can be turned on/off. The insulation layer 206 can be optionally disposed between the select gate 204 and the upper gate structure 236 to prevent leakage current between them.

The upper gate structure 236 includes an upper gate dielectric layer 234 and an upper gate 235 stacked in sequence. The upper gate dielectric layer 234 can be made of dielectric layer which allows electrons to pass through it by Fowler-Nordheim (FN) tunneling mechanism. The upper gate 235 can be made of conductive material, such as polysilicon or metal. A top surface of the upper gate structure 236 is higher than a top surface of a floating gate 224a. In addition, the upper gate structure 236 can further extend toward the select gate 204 so a portion of the upper gate structure 236 can extend beyond the sidewall of the select gate 204 and thus covers a top surface 224a_0 of the floating gate 224a.

The floating gate 224a includes two opposite first sidewalls 224a_1 arranged along an X-direction. The first sidewall 224a_1 can be a vertical or inclined sidewall instead of a curved surface. The top surface 224a_0 of the floating gate 224a is a flat or slightly inclined surface instead of a curved surface. It should be noted that the floating gate 224a shown in FIG. 2 can be a rectangular floating gate since the contour of the floating gate 224a in view AA′ is similar to a rectangle.

A floating gate dielectric layer 218 is disposed on the substrate 200 and at least between the substrate 200 and the floating gate 224a. The material of the floating gate dielectric layer 218 is, for instance, silicon oxide or other layers. During a programming operation, hot electrons are allowed to pass through the floating gate dielectric layer 218 and accumulate in the floating gate 224a.

As disclosed above, the middle structure 240 can include the insulating structure, or the middle structure 240 can include the control gate structure (the control gate structure can cover the sidewalls 224a_1, 224a_2 of the floating gate 224a so as to provide extra coupling to the floating gate). The middle structure 240 includes a thin dielectric layer 238 and a middle layer 239. The thin dielectric layer 238 is disposed on the first sidewall 224a_1 of the floating gate 224a, and the middle layer 239 is disposed in the gap between adjacent floating gates 224a. According to some embodiments of the present disclosure, a top surface of the middle structure 240a, 240b is lower than the top surface top surface 224a_0 of the floating gate 224a.

In some embodiments, when the middle structure 240 includes the control gate structure, the thin dielectric layer 238 can be a coupling dielectric layer 248 including a stack of silicon oxide/silicon nitride/silicon oxide, but is not limited thereto, and the middle layer 239 can be made of conductive material, such as poly silicon or metal, but is not limited thereto.

According to different requirements, the upper gate structure 236 can act as an erase gate structure configured to pull the electrons out of the floating gate 224a through the top corner and/or top edge of the floating gate 224a, or act as not only the erase gate structure but also a control gate structure configured to attract hot carriers from the carrier channel into the floating gate 224a. In one aspect, the upper gate structure 236 can act only as the erase gate structure but not the control gate structure when the middle structure 240b is configured to act as the control gate structure. In another aspect, the upper gate structure 236 can act as both the erase gate structure and the control gate structure when the middle structure 240a is configured to act as the insulating structure.

According to the embodiments disclosed above, the non-volatile memory device 100 includes the upper gate structure 236 disposed on the select gate 204 and the floating gate 224a. However, in other embodiments, the upper gate structure 236 may be replaced with an embedded erase gate structure (not shown) disposed under the floating gate 224a and formed in a trench (not shown) of the substrate 200. In this configuration, a lower tip (not shown) of the floating gate 224a may be partially wrapped by the embedded erase gate structure. During an erase operation of the non-volatile memory device 100, electrons originally stored in the floating gate 224a can be pulled out more effectively through the lower tip of the floating gate 224a by biasing the embedded erase gate structure.

Referring to view BB′ of FIG. 2, the select gate 204, the upper gate structure 236, and the middle structure 240a, 240b (e.g. the middle base structure or the control gate structure) are further disposed on the isolation structure 102. A portion of the middle structure 240a, 240b can be disposed between the upper gate structure 236 extending beyond the sidewall of the select gate 204 and the isolation structure 102, or the portion of the middle structure 240a, 240b can be disposed between the upper gate structure 236 and the substrate 200.

Referring to view CC′ of FIG. 2, each floating gate 224a includes two opposite second sidewalls 224a_2 arranged along the Y-direction. The second sidewall 224a_2 can be a vertical or inclined sidewall. An upper portion of a second sidewall 224a_2 of the floating gate 224a can be covered with the upper gate structure 236, and a lower portion of the second sidewall 224a_2 of the floating gate 224a can be covered with the middle structure 240a, 240b (e.g. the middle base structure or the control gate structure). According to some embodiments of the present disclosure, 60% to 95% of the surface area of each second sidewall 224a_2 is covered with the middle layer 239, and thus the contact area between the upper gate structure 236 and the second sidewall 224a_2 is small. In addition, because of the presence of the middle structure 240a, 240b, a bottom surface of the upper gate structure 236 extending beyond the second sidewall 224a_2 of the floating gate 224a can be spaced apart from the isolation structure 102, the floating gate dielectric layer 218, and the substrate 200.

According to some embodiments of the present disclosure, the non-volatile memory device can further include other components, such as vias, bit lines, interlayer dielectric and so forth, and the structure shown in FIG. 2 can be further modified based on actual requirements.

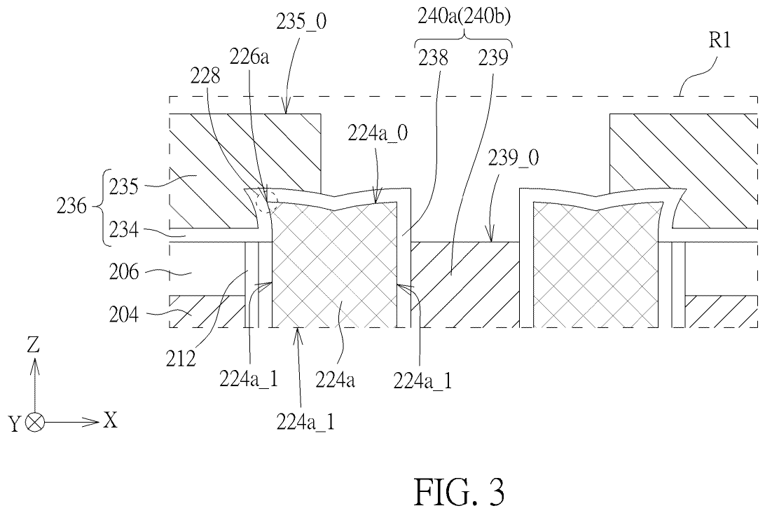

FIG. 3 is an enlarged cross-sectional view of a region R1 of a non-volatile memory device shown in FIG. 2 according to some embodiments of the present disclosure. Referring to FIG. 3, the floating gate 224a includes two first top edges 226a_1 which are opposite each other and arranged along a first direction, such as an X-direction. One of the first top edges 226a_1 is adjacent to the select gate 204, and the other one of the first top edges 226a_1 is away from the select gate 204. The floating gate 224a may further include a top tip 228 which extends toward the upper gate structure 236 and is thus laterally separated from the bottom surface of the floating gate 224a. Because the top tip 228 extends toward the upper gate structure 236, the top tip 228 can be at least partially embedded in the upper gate structure 236. The top edge of the top tip 228 is the first top edge 226a that is adjacent to the select gate 204.

By biasing the upper gate structure 236, most of the electrons stored in the floating gate 224a can be pulled out through the top tip 228 embedded in the upper gate structure 236. The first sidewalls 224a_1 of the floating gate 224a arranged along the first direction such as an X-direction are connected to the first top edges 226a_1, respectively. The second sidewalls (not shown) of the floating gate 224a are arranged along a second direction such as a Y-direction, and covered with the dielectric middle layer 239 made of dielectric material or covered with the conductive middle layer 239 acting as the control gate (i.e. coupling gate). Since 65% to 95% of the second sidewalls (i.e. the sidewalls perpendicular to a Y-direction) are covered with the middle layer 239, and both first top edges 226a_1 are higher than the lowest bottom surface of the upper gate 235, the coupling ratio between the upper gate structure 236 and the underlying floating gate 224a would not be changed significantly even if there is a misalignment between the upper gate 235 and the floating gate 224a. Thus, the uniformity in electrical characteristics among the non-volatile memory devices can be improved.

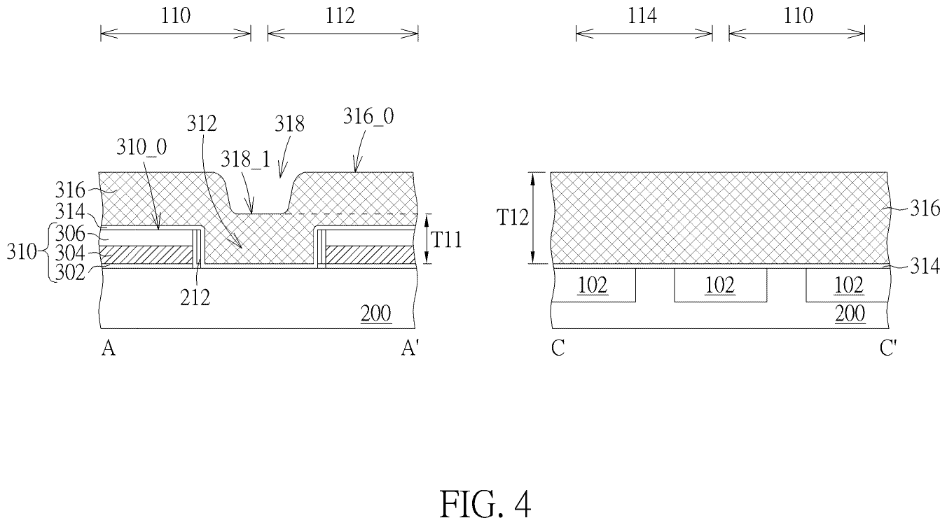

FIGS. 4-13 are cross-sectional views at various stages in the manufacturing of non-volatile memory devices, such as those shown in FIGS. 1-3, according to some embodiments of the present disclosure. In FIGS. 4-13, view AA′ corresponds to the line A-A′ of FIG. 1, view BB′ corresponds to the line B-B′ of FIG. 1, and view CC′ corresponds to the line C-C′ of FIG. 1.

Referring to view AA′ and view CC′ of FIG. 4, a structure formed at this manufacturing stage includes at least a substrate 200, two stack structures 310, a dielectric spacer 212, a floating gate dielectric layer 314, and a floating gate layer 316.

According to some embodiments of the present disclosure, the substrate 200 may be a semiconductor substrate with suitable conductivity type, such as p-type or n-type. The material of the substrate 200 may include silicon, germanium, gallium nitride, or other suitable semiconductor materials, but not limited thereto.

The stack structures 310 are disposed on the substrate 200 and laterally spaced apart from each other. Each of the stack structures 310 includes a select gate dielectric layer 302, a select gate layer 304, and an insulation layer 206 stacked in order. The select gate layer 304 is made of conductive material. In the following manufacturing processes, the select gate layer 304 can be patterned to form a select gate (not shown), which is configured to turn on/off a carrier channel in the substrate 200 underlying the select gate layer 304. The insulation layer 206 is made of insulating material, such as silicon oxide or silicon oxynitride, but not limited thereto, which is used to electrically isolate the select gate layer 304 from layers disposed above the select gate layer 304.

The dielectric spacer 212 is formed on the sidewalls 211, 213 of the stack structures 310. The material of the dielectric spacer 212 is, for instance, silicon oxide/silicon nitride/silicon oxide or silicon nitride/silicon oxide.

The floating gate dielectric layer 314 is formed on the stack structures 310 and in a gap 312 between the stack structures 310. The material of the floating gate dielectric layer 314 is, for instance, silicon oxide, or other layers that allow hot electrons pass through it.

The floating gate layer 316 is disposed on the floating gate dielectric layer 314. The thickness of the floating gate layer 316 can be properly controlled so that the floating gate layer 316 can conform to the shape of the underlying structures. The floating gate layer 316 can be made of conductive material such as poly silicon or metal, but is not limited thereto.

The floating gate layer 316 includes a recess region 318 located directly above the gap 312. The bottom surface 318_1 of the recess region 318 may be higher than the top surface 310_0 of the stack structure 310. The thickness T11 of the floating gate layer 316 under the recess region 318, as shown in view AA′, is thinner than the thickness T12 of the floating gate layer 316, as shown in view CC′.

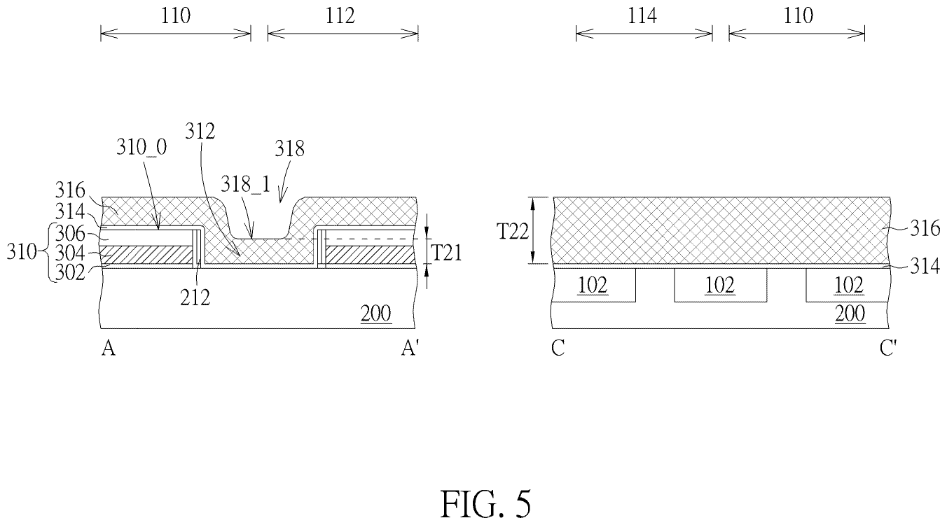

FIG. 5 shows schematic cross-sectional views after the manufacturing stage shown in FIG. 4. In FIG. 5, an etch-back process is performed to reduce the thickness of the floating gate layer 316 to the desired value. The floating gate layer 316 is etched until the bottom surface 318_1 of the recess region 318 is lower than the top surface 310_0 of the stack structure 310. When the etching back process is complete, the thickness T21 of the floating gate layer 316 under the recess region 318, as shown in view AA′, is still thinner than the thickness T22 of the floating gate layer 316, as shown in view CC′.

In some embodiments, if the thickness of the floating gate layer 316 can be properly controlled to the desired value during the deposition process as shown in FIG. 4, the etch-back process shown in FIG. 5 may be omitted.

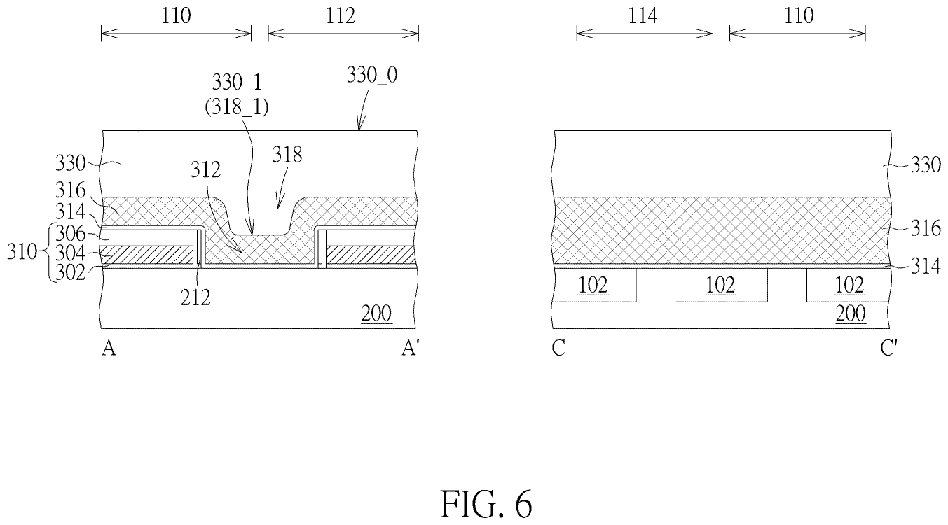

FIG. 6 shows schematic cross-sectional views after the manufacturing stage shown in FIG. 5. In FIG. 6, a first mask layer 330 is formed on the floating gate layer 316 and filled into the recess region 318. The forming method of the first mask layer 330 is, for instance, a chemical vapor deposition method, but is not limited thereto. The material of the first mask layer 330 is different from the material of the floating gate layer 316. For example, the first mask layer 330 may be made of dielectric material or semiconductor material. In some embodiments, the first mask layer 330 is made of dielectric material, such as silicon oxide, silicon nitride, or silicon oxynitride. After the formation of the first mask layer 330, a planarization process is performed on the first mask layer 330 until a planarized top surface 330_0 is obtained.

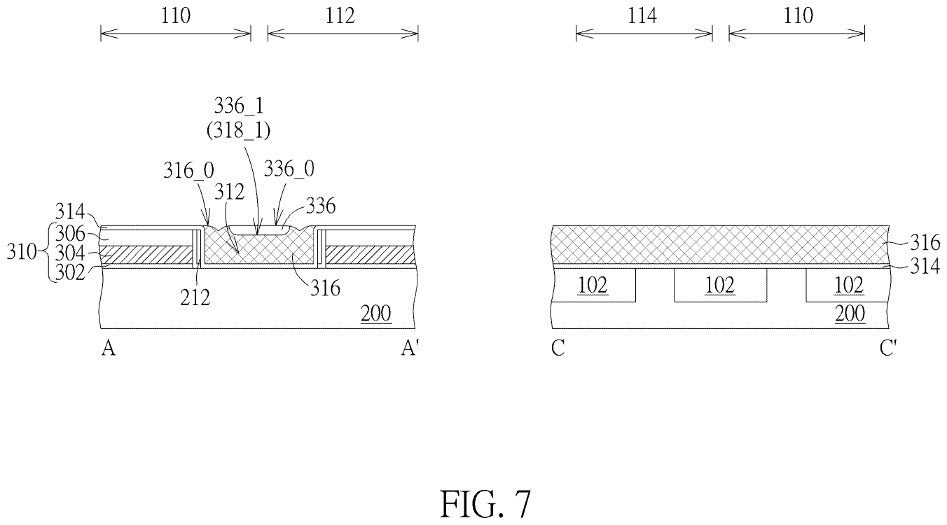

FIG. 7 shows schematic cross-sectional views after the manufacturing stage shown in FIG. 6. Referring to FIG. 7 as well as FIG. 6, an etch-back process or a series of etch-back processes can be performed on the first mask layer 330 and the floating gate layer 316 to remove the upper portions of both the first mask layer 330 and the floating gate layer 316. During the etch-back process, the top surface 316_0 of the floating gate layer 316 can be exposed from the first mask layer 330.

In some embodiments, when the etching selectivity between the first mask layer 330 and the floating gate layer 316 ranges from 0.7 to 1.3, the upper portion of the first mask layer 330 and the upper portion of the floating gate layer 316 may be considered to be removed simultaneously. In some embodiments, when the etching selectivity between the first mask layer 330 and the floating gate layer 316 is not within the range from 0.7 to 1.3, the upper portion of the first mask layer 330 and the upper portion of the floating gate layer 316 may be removed separately by performing a series of etch-back processes.

When the etch-back process is complete, as shown in FIG. 7, the first mask 336 is formed in the recess region 318, and the upper portion of the floating gate layer 316 is removed to leave a lower portion of the floating gate layer 316 in the gap 312. The floating gate layer 316 in the gap 312 includes the top surfaces 316_0 that are laterally separated and exposed from the first mask 336.

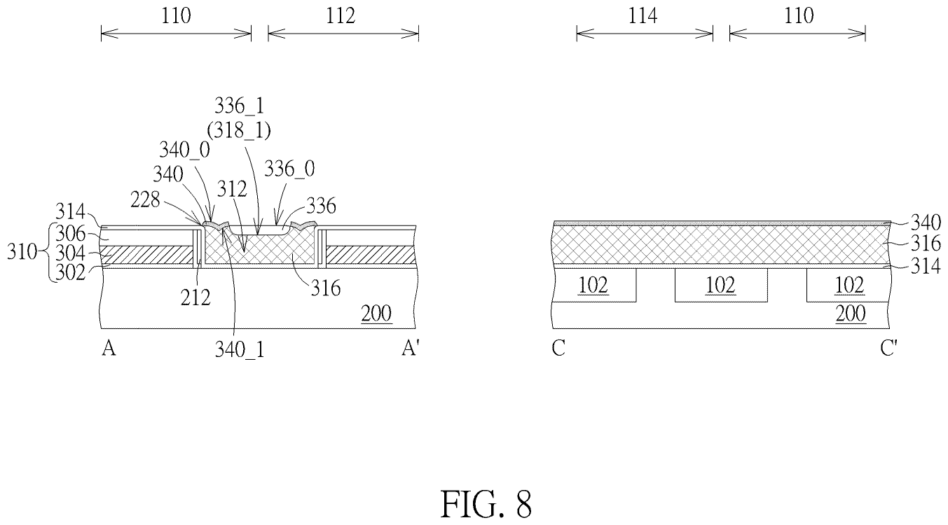

FIG. 8 shows schematic cross-sectional views after the manufacturing stage shown in FIG. 7. Referring to FIG. 8, under the coverage of the first mask 336, the top surfaces 316_0 of the floating gate layer 316 exposed from the first mask 336 are converted into second masks 340.

The conversion process may include a thermal treatment process, an ion implantation process, and/or an amorphization process. In some embodiments, when the conversion process includes the thermal treatment process, the exposed top surfaces of the floating gate layer 316 may be oxidized and/or nitrided (in such a case, the first mask layer 330 of FIG. 6 would be materials other than nitride and its top surface is resistant to nitridation) to form the second masks 340 made of oxide and/or nitride, such as silicon oxide, silicon nitride, silicon oxynitride, or a combination thereof. In some embodiments, when the conversion process includes the ion implantation process, the exposed top surfaces of the floating gate layer 316 may be modified to form the second masks 340 containing dopants. The dopants may include carbon, oxygen, nitrogen, or a combination thereof, but are not limited thereto. In some embodiments, when the conversion process includes the amorphization process, the exposed top surfaces of the floating gate layer 316 may be modified to form the second masks 340 containing amorphous structures.

In some embodiments, the maximum thickness of the first mask 336 is greater than the maximum thickness of each of the second masks 340, and the bottom surface 336_1 of the first mask 336 is lower than the bottom surface 340_1 of the second masks 340. Because the material and/or structure of the first mask 336 is different from the material and/or structure of the second mask 340, the etching selectivity between the first mask 336 and the second mask 340 is greater than 3 in the subsequent process of removing the first mask 336.

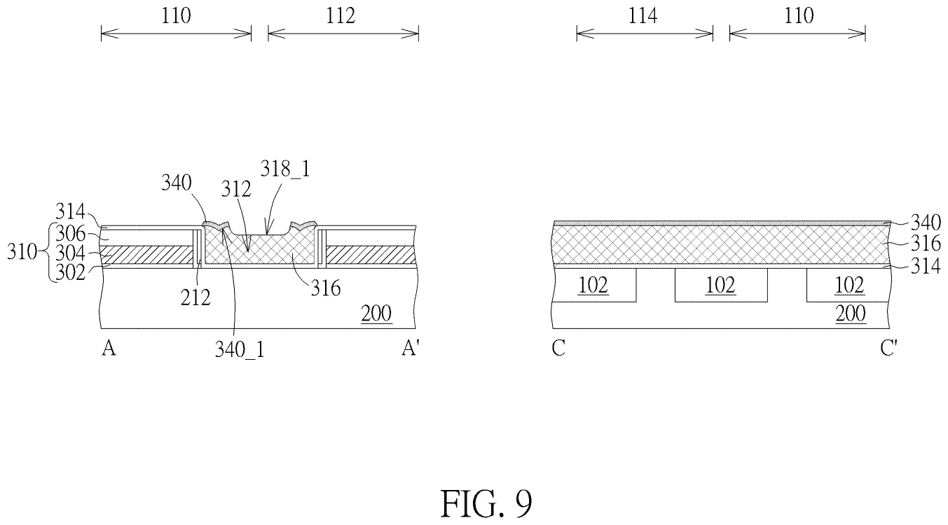

FIG. 9 shows schematic cross-sectional views after the manufacturing stage shown in FIG. 8. Referring to FIG. 9, the first mask 336 in the recess region 318 is removed to expose the bottom surface 318_1 of the recess region 318. Because the etching selectivity between the first mask 336 and the second mask 340 during the removal of the first mask 336 is greater than 3, such as 5, 10, 20, 100, or any intervening values, the second mask 340 can remain on the floating gate layer 316 when the entire first mask 336 is removed. In some embodiments, when the first mask 336 in the recess region 318 is removed, the bottom surface 318_1 of the recess region 318 is lower than the bottom surface 340_1 of each of the second masks 340.

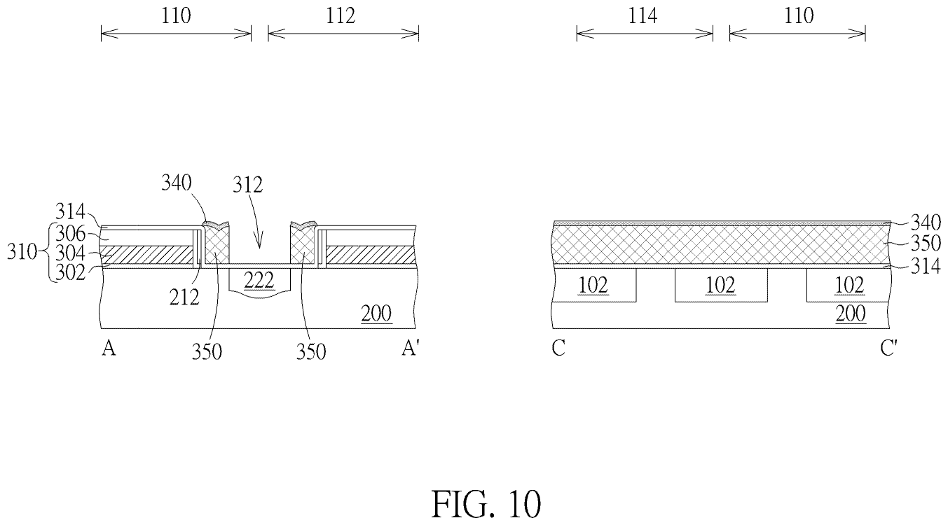

FIG. 10 shows schematic cross-sectional views after the manufacturing stage shown in FIG. 9. Referring to FIG. 10, an anisotropic etching process is performed on the floating gate layer 316 using the second mask 340 as an etch mask. As a result, the floating gate layer 316 in the gap 312 can be divided into two separate portions, i.e., two floating gate layers 350. The floating gate layers 350 in the first memory cell region 110 and the second memory cell region 112 can be laterally separated from each other in the X-direction, and each of the floating gate layers 350 can extend along the Y-direction. Because each of the floating gate layers 350 is a self-aligned structure with a vertical or sloped sidewall, there is no need to use the photolithography process to form the floating gate layers 350.

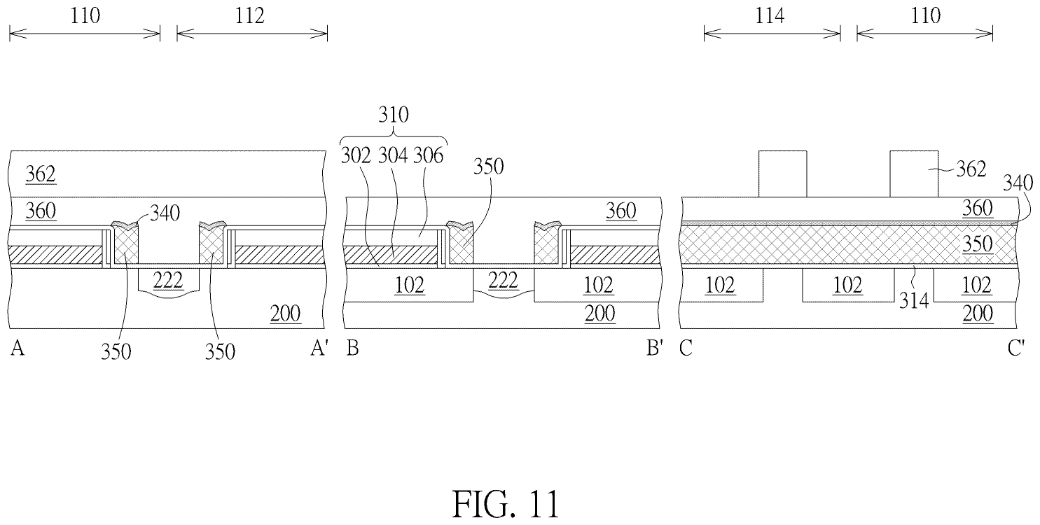

FIG. 11 shows schematic cross-sectional views after the manufacturing stage shown in FIG. 10. Referring to view AA′ of FIG. 10, a source region 222 is formed in the substrate 200. In some embodiments, the forming method of the source region 222 includes, for instance, performing an ion implantation process. The implanted dopant can be an n-type or p-type dopant as decided according to the design of the memory device.

After the formation of the source region 222, a photolithography process is performed to form a stacked layer on the stack structure 310 and the floating gate layer 350. Referring to view AA′ and view CC′ of FIG. 11, the stacked layer may include at least a bottom layer 360 and a patterned photoresist layer 362 stacked in sequence from bottom to top. The bottom layer 360 may be a single layer or a stacked layer including an organic dielectric layer (ODL), spin-on carbon (SOC), a bottom anti-reflective coating (BARC), and/or other layers. The bottom layer 360 can fill the gap 312 and have a flat top surface. In some embodiments, in order to form the bottom layer 360 with a flat top surface, at least one sub-layer of the bottom layer 360 can be formed using a spin coating process.

Referring to view AA′ and view CC′ of FIG. 11, the patterned photoresist layer 362 includes at least two strip-shaped features. Each of the strip-shaped features extends along the X-direction as shown in view AA′, and the strip-shaped features are separated from each other along the Y-direction as shown in view CC′.

Referring to view BB′ of FIG. 11, the bottom layer 360 is not covered by the patterned photoresist layer 362. Therefore, the exposed bottom layer 360 is removed in the subsequent etching process.

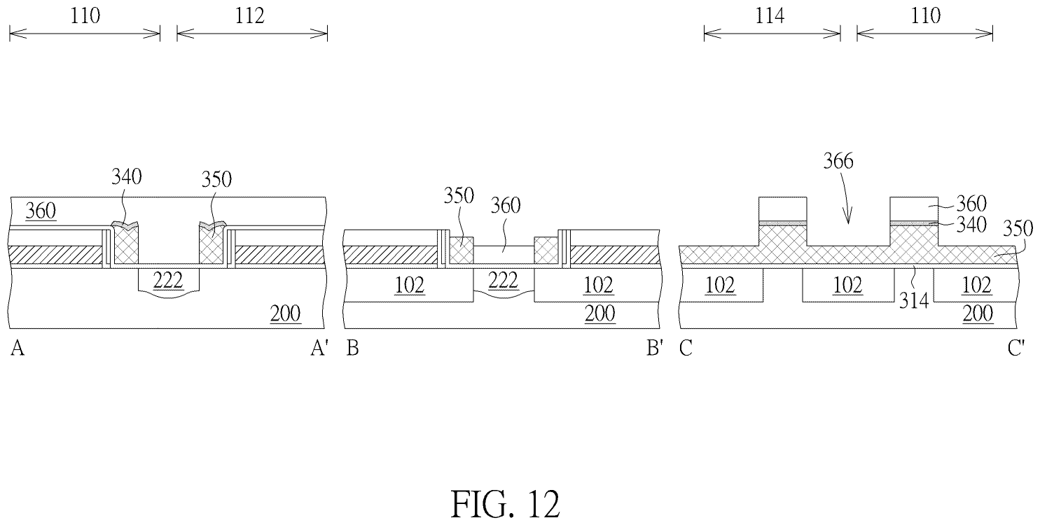

FIG. 12 shows schematic cross-sectional views after the manufacturing stage shown in FIG. 11. Referring to FIG. 11 and FIG. 12, an etching process or a series of etching processes is performed to transfer the patterns of the patterned photoresist layer 362 into the underlying floating gate layer 350.

Referring to view AA′ of FIG. 12, the bottom layer 360 originally covered by the patterned photoresist layer 362 can be etched slightly during the etching process. As a result, the thickness of the bottom layer 360 can be reduced.

Referring to view BB′ of FIG. 12, the bottom layer 360 that is not originally covered by the patterned photoresist layer 362 can be etched to a greater extent compared to the portion shown in view AA′ of FIG. 12. In addition, the portions of the second mask 340 and the floating gate layer 350 that are not originally covered by the patterned photoresist layer 362 can be etched during the etching process.

Referring to view CC′ of FIG. 12, the portions of the floating gate layer 350 that are not originally covered by the patterned photoresist layer 362 are etched. As a result, at least one recess region 366 can be formed in the floating gate layer 350 during the etching process.

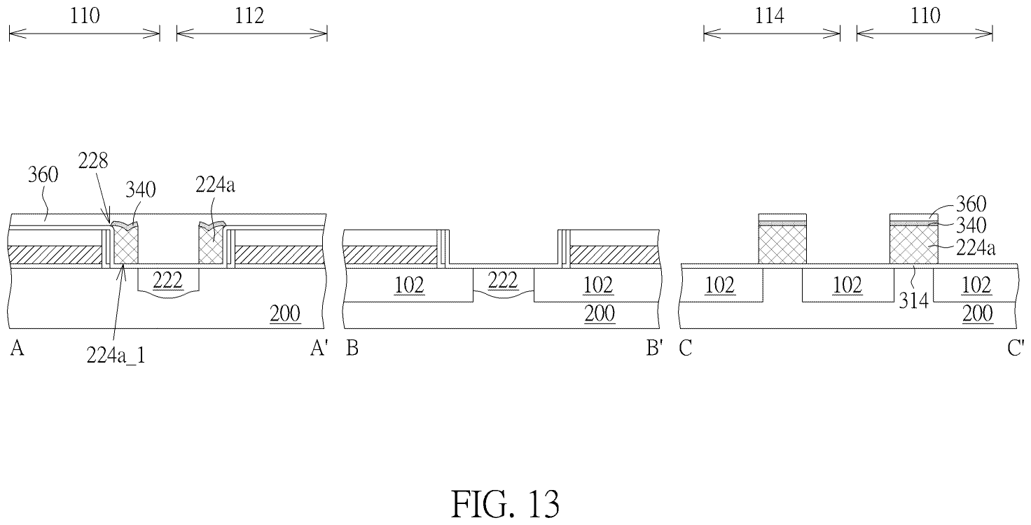

FIG. 13 shows schematic cross-sectional views after the manufacturing stage shown in FIG. 12. The etching process of FIG. 12 can continue until several floating gates 224a, as shown in FIG. 13, are formed.

Referring to view AA′ of FIG. 12, the bottom layer 360 that is originally covered by the patterned photoresist layer 362 can be further etched after the manufacturing stage shown in FIG. 12. As a result, the thickness of the bottom layer 360 can be further reduced.

Referring to view BB′ of FIG. 12, the bottom layer 360 that is not originally covered by the patterned photoresist layer 362 can be removed completely when the etching process is complete. In addition, the portions of the second mask 340 and the floating gate layer 350 that are not originally covered by the patterned photoresist layer 362 can be removed completely when the etching process is complete.

Referring to view CC′ of FIG. 12, the portions of the floating gate layer 350 that are originally not covered by the patterned photoresist layer 362 are removed completely, resulting in the formation of floating gates 224a that are separated from each other.

After the manufacturing stage shown in FIG. 13, the remaining bottom layer 360 can be stripped, and the second mask 340 covering the floating gate 224a can also be removed. After the removal of the second mask 340, the floating gate 224a can include a top tip 228 that is laterally separated from the bottom surface of the floating gate 224a.

Afterward, the select gate layer 304 may be patterned to form a select gate 204 as shown in FIGS. 1-3. At least one drain region 244, such as two drain regions 244, may be formed at the sides of the select gates 204, which can be electrically coupled to each other through vias or contacts in subsequent manufacturing processes.

Subsequently, other electronic components can be manufactured through suitable manufacturing processes to obtain a non-volatile memory device similar to the structure shown in FIGS. 1-3.

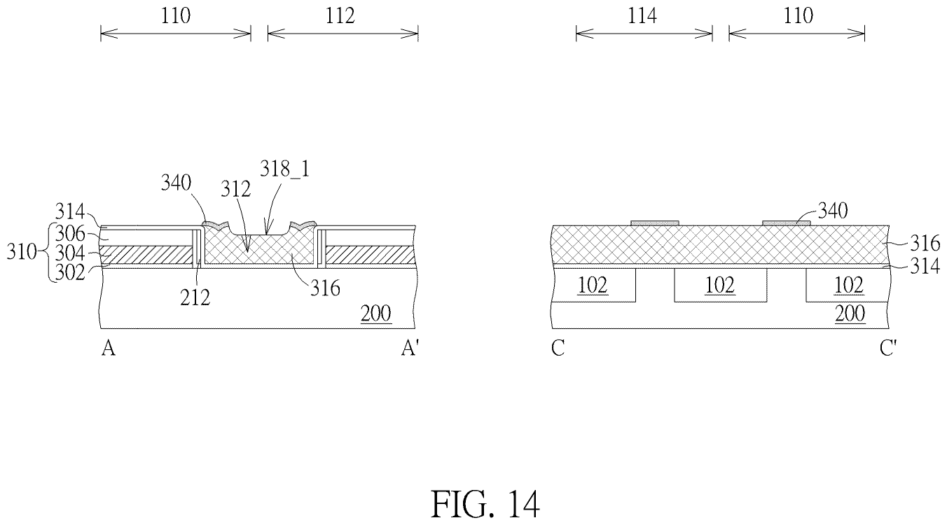

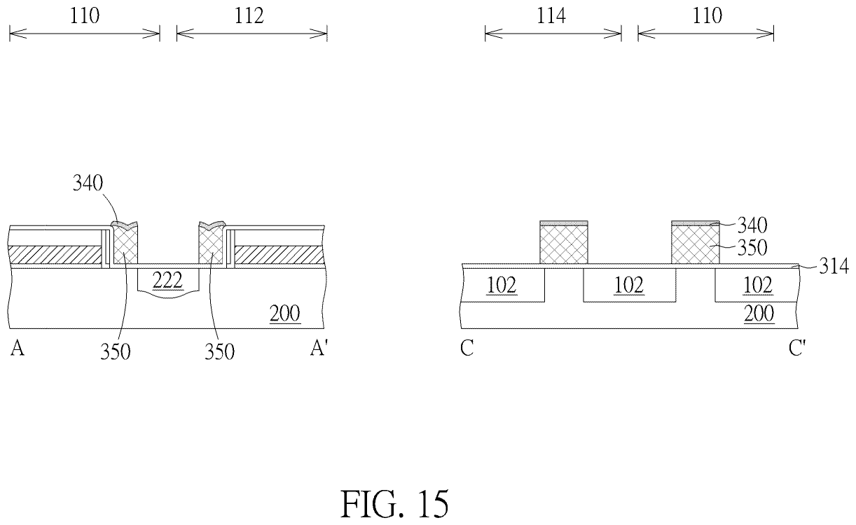

FIGS. 14-15 are schematic cross-sectional views at various stages in the manufacturing of non-volatile memory devices, such as those shown in FIGS. 1-3, according to an alternative embodiment of the present disclosure. Some of the manufacturing processes of the embodiments shown in FIGS. 4-13 may be replaced with or modified by the manufacturing processes shown in FIGS. 14-15, and only the main differences between the embodiments are described for the sake of brevity. In FIGS. 14-15, view AA′ corresponds to the line A-A′ of FIG. 1, view BB′ corresponds to the line B-B′ of FIG. 1, and view CC′ corresponds to the line C-C′ of FIG. 1.

Referring to FIG. 8 and FIG. 14, the manufacturing stage of FIG. 14 follows the manufacturing stage of FIG. 8. In view CC′ of FIG. 8, the second mask 340 is continuously distributed in the Y-direction. Then, the second mask 340 is patterned using a photolithography process and an etching process so as to obtain the second mask 340 discontinuously distributed along the Y-direction, as shown in view CC′ of FIG. 14.

Subsequently, referring to FIG. 14 and FIG. 15, an etching process or a series of etching processes is performed using the second masks 340 as an etch mask to transfer the patterns of the second masks 340 into the underlying floating gate layer 350. As a result, as shown in FIG. 15, several floating gates 224a are formed. During the pattern transfer process, no organic dielectric layer (OLD), spin-on carbon (SOC), or bottom anti-reflective coating (BARC) is present on the floating gate layer 350. Therefore, no organic or conductive residue remains on the substrate 200 when the floating gates 224a are formed.

Other manufacturing processes analogous to those shown in FIGS. 4-13 may be performed so as to obtain a non-volatile memory device similar to the structures shown in FIGS. 1-3.

According to the embodiments disclosed above, the manufacturing processes illustrated in FIGS. 4-15 can be performed to manufacture a non-volatile memory device similar to the structures shown in FIGS. 1-3. In alternative embodiments, the manufacturing processes illustrated in FIGS. 4-15 can also be modified to manufacture a non-volatile memory device in which an embedded erase gate structure (not shown) is formed in a trench (not shown) of the substrate 200. In this configuration, a lower tip (not shown) of the floating gate 224a may be partially wrapped by the embedded erase gate structure. During an erase operation of the non-volatile memory device 100, electrons originally stored in the floating gate 224a can be pulled out more effectively through the lower tip of the floating gate 224a by applying a bias to the embedded erase gate structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing a non-volatile memory device, comprising:
providing a substrate;
forming two stack structures on the substrate, each stack structure comprising a select gate layer and a select gate dielectric layer, and a gap being formed between the stack structures;
forming a floating gate layer on the substrate, the floating gate layer covering the two stack structures and the substrate, and filled into the gap, wherein the floating gate layer comprises a recess region;
filling a first mask layer into the recess region;
removing an upper portion of the first mask layer to form a first mask in the recess region;
removing an upper portion of the floating gate layer to leave the floating gate layer in the gap, wherein two top surfaces of the floating gate layer in the gap are laterally separated from the first mask;
converting the two top surfaces of the floating gate layer into second masks under the coverage of the first mask;
removing the first mask in the recess region; and
etching the floating gate layer using the second masks as an etch mask.

2. The method for manufacturing a non-volatile memory device of claim 1, wherein, when filling the first mask layer into the recess region, a bottom surface of the first mask layer is lower than a top surface of each of the stack structures.

3. The method for manufacturing a non-volatile memory device of claim 1, wherein, in removing the upper portion of the floating gate layer, the floating gate layer comprised a top surface exposed by the first mask.

4. The method for manufacturing a non-volatile memory device of claim 1, wherein removing the upper portion of the first mask layer and removing the upper portion of the floating gate layer are performed simultaneously.

5. The method for manufacturing a non-volatile memory device of claim 1, wherein, during the thermal treatment process, each top surface of the floating gate layer in the gap is oxidized to form the second masks.

6. The method for manufacturing a non-volatile memory device of claim 1, wherein a material of the first mask is different from a material of the second masks.

7. The method for manufacturing a non-volatile memory device of claim 6, wherein the material of the first mask includes nitride or oxynitride, and the material the second mask includes oxide or oxynitride material.

8. The method for manufacturing a non-volatile memory device of claim 6, wherein the etching selectivity between the first mask and the second masks is greater than 3 during the removal of the first mask.

9. The method for manufacturing a non-volatile memory device of claim 1, wherein a maximum thickness of the first mask is greater than a maximum thickness of each of the second masks.

10. The method for manufacturing a non-volatile memory device of claim 1, wherein after removing the first mask in the recess region, a bottom surface of the recess region is lower than a bottom surface of each of the second masks.

11. The method for manufacturing a non-volatile memory device of claim 1, wherein, after etching the floating gate layer, the method further comprises patterning the floating gate layer to form a plurality of floating gates separated from each other.

12. The method for manufacturing a non-volatile memory device of claim 1, wherein, before etching the floating gate layer, the second masks are continuously distributed in a direction in a top view, and the method further comprises: before etching the floating gate layer, patterning the second masks such that the second masks are discontinuously distributed along the direction.

13. The method for manufacturing a non-volatile memory device of claim 1, wherein at least one floating gate is formed by etching the floating gate layer, and the at least one floating gate comprises a top tip extending toward one of the stack structures.

14. The method for manufacturing a non-volatile memory device of claim 13, wherein a portion of the top tip is laterally separated from a bottom surface of the floating gate.

15. A non-volatile memory device comprising at least one memory cell, the at least one memory cell comprising:
a substrate;
a select gate disposed on the substrate; and
a floating gate disposed on the substrate and laterally separated from the select gate, and comprising:
two first top edges disposed opposite each other along a first direction, each first top edge being higher than a top surface of the select gate, wherein one of the first top edges is adjacent to the select gate and laterally separated from a bottom surface of the floating gate;
two first sidewalls disposed opposite each other along the first direction and connected respectively to the two first top edges; and
two second sidewalls disposed opposite each other along a second direction different from the first direction.

16. The non-volatile memory device of claim 15, wherein one of the first sidewalls is opposite to the select gate and is a vertical or sloped sidewall.

17. The non-volatile memory device of claim 15, wherein the two second sidewall are vertical or sloped sidewalls respectively.

18. The non-volatile memory device of claim 15, further comprising:
a middle structure covering one of the two first sidewalls of the floating gate and disposed opposite to the select gate along the first direction;
wherein the floating gate is located between the middle structure and the select gate, a top surface of the middle structure is equal to or lower than at least one of the two first top edges of the floating gate, and the middle structure comprises an insulating structure or a control gate.

19. The non-volatile memory device of claim 15, wherein the floating gate further comprises a top tip, and a top edge of the top tip is the first top edge adjacent to the select gate.

20. The non-volatile memory device of claim 15, further comprising an upper gate structure covering the select gate and the floating gate, wherein the first top edge adjacent to the select gate is embedded in the upper gate structure.
